(19) United States
(12) Patent Application Publication
(10) Pub. No.: US 2013/0106458 A1
(43) Pub. Date: May 2, 2013

(54) HOLDER FOR MEASUREMENT AND MEASUREMENT APPARATUS

(71) Applicants: Motoshi SETO, Kanagawa-ken (JP); Hiroaki Murakami, Mie-ken (JP); Kazuhiro Ilzuka, Kanagawa-ken (JP)

(72) Inventors: Motoshi SETO, Kanagawa-ken (JP); Hiroaki Murakami, Mie-ken (JP); Kazuhiro Ilzuka, Kanagawa-ken (JP)

(21) Appl. No.: 13/664,763

(22) Filed: Oct. 31, 2012

(30) Foreign Application Priority Data
Oct. 31, 2011 (JP) 2011-239636

(51) Int. Cl. G01R 31/26

(52) U.S. Cl. 324/756.02

(57) ABSTRACT

A holder for measurement configured to be capable of holding an object of measurement, the object of measurement included a package including a plurality of semiconductor chips and a conduction portion exposed to the outside through a lateral surface of the package, including: a support board including a through-hole; a fixation portion configured to fix the object of measurement to the support board; and a probe portion movable in at least one axial direction with respect to the support board, and configured to be capable of coming into contact with the conduction portion.

### CROSS-REFERENCE TO RELATED APPLICATIONS

This application is based upon and claims the benefit of priority from prior Japanese Patent Application No. 2011-239636, filed Oct. 31, 2011, the entire contents of which are incorporated herein by reference.

### FIELD

Embodiments described herein relate generally to a holder for measurement and a measurement apparatus.

### BACKGROUND

A semiconductor device includes a plurality of semiconductor chips, a resin-made package configured to seal the plurality of semiconductor chips, and a plurality of electrodes. The plurality of electrodes are provided to the outside of the package in order to electrically communicate with the plurality of semiconductor chips.

In a BGA (ball grid array)-type semiconductor device, multiple ball-type electrodes are provided to the undersurface of the package in a matrix.

It has been desired that such a holder for measurement be capable of meeting a more accurate inspection.

### BRIEF DESCRIPTION OF THE DRAWINGS

FIGS. 1A and 1B are schematic diagrams illustrating the constitution of a holder for measurement of a first embodiment.

FIGS. 2A and 2B are schematic diagrams showing an example of an object of measurement.

FIGS. 3A and 3B are schematic plan views illustrating a part of the inside of a package.

FIGS. 4A and 4B are schematic cross-sectional views for explaining how a semiconductor device is held.

FIGS. 5A and 5B are schematic diagrams showing other examples of probe portions.

FIGS. 6A and 6B are schematic diagrams showing the other examples of the probe portions.

FIGS. 7A and 7B are schematic diagrams illustrating a measurement apparatus of a second embodiment.

FIGS. 8A to 8C are diagrams showing an example of how a location of a heat source is detected.

FIG. 9 is a diagram showing a relationship between a depth D and a phase difference φ1.

FIG. 10 is a schematic diagram illustrating a measurement apparatus of a third embodiment.

FIGS. 11A to 11C are diagrams showing an example of how the location of a heat source is detected.

FIG. 12 is a schematic diagram illustrating a measurement apparatus of a fourth embodiment.

FIG. 13 is a schematic diagram illustrating a measurement apparatus of a 5th embodiment.

FIG. 14 is a schematic diagram showing another application example.

FIGS. 15A and 15B are schematic diagrams showing an example of a mounting board.

### DETAILED DESCRIPTION

According to an aspect, A holder for measurement configured to be capable of holding an object of measurement, the object of measurement included a package including a plurality of semiconductor chips and a conduction portion exposed to the outside through a lateral surface of the package, including: a support board including a through-hole; a fixation portion configured to fix the object of measurement to the support board; and a probe portion movable in at least one axial direction with respect to the support board, and configured to be capable of coming into contact with the conduction portion.

Descriptions will be hereinafter provided for the embodiments. It will be understood that when an element is referred to as being “electrically connected to” another element, it can be not only directly connected but also connected to the other element or intervening elements may be present.

It should be noted that: the drawings are schematic or conceptual; and the relationship between the thickness and width of each component, coefficients of size ratio among components, and the like are not necessarily equal to the real ones. In addition, even when the same components are depicted, the dimensions of the components and coefficients of ratio among the components may differ from one drawing to another.

Furthermore, components which are the same as those previously described with regard to previously-shown drawings will be denoted by the same reference signs throughout the description and drawings of the application concerned. Detailed descriptions for such components will be omitted appropriately.

### First Embodiment

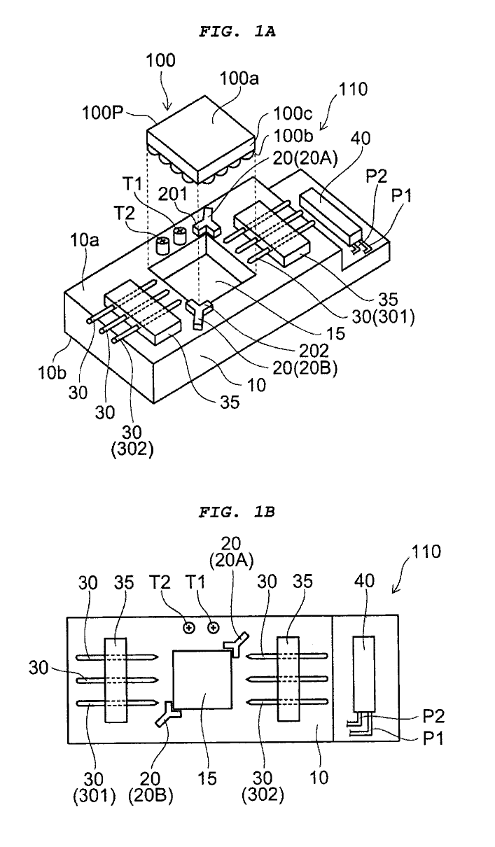

FIGS. 1A and 1B are schematic diagrams illustrating the constitution of a holder for measurement of a first embodiment.

FIG. 1A shows a schematic perspective view of a holder 110 for measurement of the first embodiment, and FIG. 1B shows a schematic overhead view of the holder 110 for measurement of the first embodiment.

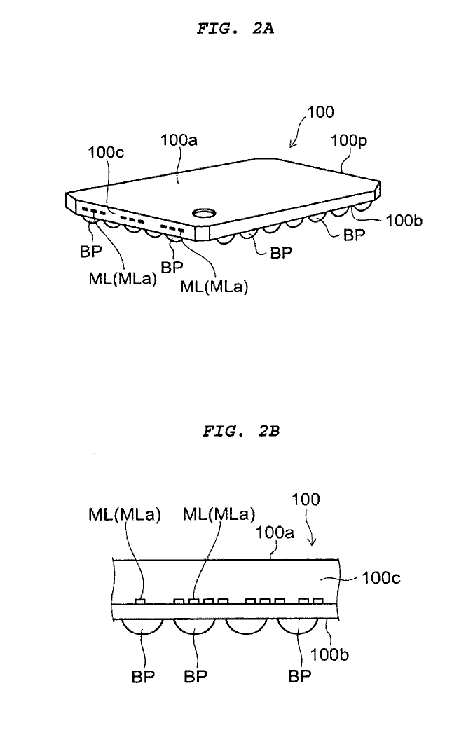

FIGS. 2A and 2B are schematic diagrams showing an example of an object of measurement.

FIG. 2A shows a schematic perspective view of a semiconductor device which is the example of the object of measurement, and FIG. 2B shows a lateral surface of the semiconductor device.

As shown in FIGS. 1A and 1B, the object (the object of measurement) held by the holder 110 for measurement of the embodiment is, for example, a semiconductor device 100. The object of measurement is not limited by the semiconductor device. The object of measurement may be for example a system included the semiconductor device such as SSD and SD™ card.

As shown in FIGS. 2A and 2B, the semiconductor device 100 includes a package 100P, electrodes BP, and conduction portions ML. The package 100P includes a top surface 100a, an undersurface 100b and lateral surfaces 100c. The electrodes BP are provided to the undersurface 100b. The conduction portions ML are exposed to the outside through the lateral surfaces 100c, and configured to electrically communicate with the electrodes BP.

The conduction portions ML are connected to pads of chips (not illustrated) included in the package 100P, for example.

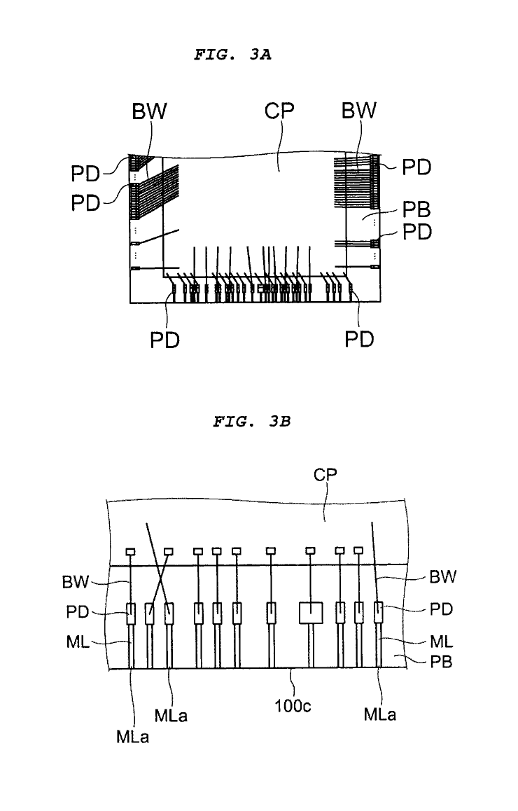

FIGS. 3A and 3B are schematic overhead views illustrating a part of the inside of the package.

FIG. 3B is a magnified schematic overhead view illustrating the part of the inside of the package shown in FIG. 3A.

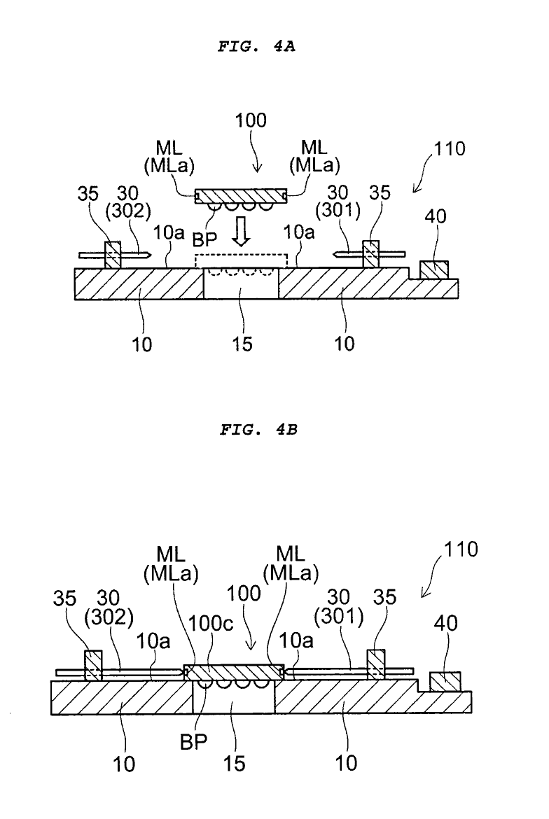

FIGS. 4A and 4B are schematic cross-sectional views for explaining how the semiconductor device is held.

As shown in FIGS. 3A and 3B, a printed wiring board PB is provided inside the package 100P. Semiconductor chips CP are mounted on the printed wiring board PB. The semiconductor chips CP are electrically connected to the pads PD, which are provided to the printed wiring board PB, by use of bonding wires BW.

The ball-shaped electrodes BP, for example, are provided to the undersurface of the printed wiring board PB. The pads PD provided on the printed wiring board PB are electrically connected to the electrodes BP provided to the undersurface of the printed wiring board PB through the conduction portions ML.

The conduction portions ML are plated with gold (Au). Parts of the respective conduction portions ML extend to the edges of the printed wiring board PB. The parts of the respective conduction portions ML are provided in order to conduct the respective conduction portions to each other when the conduction portions ML are plated.

In a case where the package 100P is provided in a way that covers the semiconductor chips CP, end surfaces MLa of the respective conduction portions ML are exposed to the outside through the lateral surfaces 100c of the package 100P. The number of electrodes BP is equal to the number of end surfaces MLa. The multiple electrodes BP correspond to the respective end surfaces MLa on a one-to-one basis.

The holder 110 for measurement of the embodiment obtains the electrical conduction between the pads of the semiconductor chips CP and the outside by use of the end surfaces MLa of the conduction portions ML.

As shown in FIGS. 1A and 1B, the holder 110 for measurement includes a support board 10, fixation portions 20, and probe portions 30.

The support board 10 is a member in order to place the semiconductor device 100. The semiconductor device 100 is placed there with the undersurface 100b of the package 100P in parallel with a first surface 10a of the support board 10, for example.

A through-hole 15 may be provided in a portion of the support board 10. The semiconductor device may be placed above the through-hole 15. The through-hole 15 is the one which penetrates the support board 10. As shown in FIGS. 4A and 4B, the size of the opening of the through-hole 15 is smaller than the external size of the package 100P, and is slightly larger than an area of the undersurface 100b of the package 100P, for example. For this reason, when the semiconductor device 100 is placed on the support board 10, the edge portions of the undersurface 100b of the package 100P sit on the first surface 10a, and the area of the package 100P in which the electrodes BP are provided is placed above the through hole 15.

When, as described above, the semiconductor device 100 is placed fittingly in the location of the through-hole 15, there is nothing that covers either the top surface 100a or the undersurface 100b of the package 100P.

The fixation portions 20 are provided to the support board 10. The fixation portions 20 are movable along the first surface 10a of the support board 10, for example.

For example, the fixations 20 includes paired fixation members 20A, 20B in order to hold the package 100P. The paired fixation members 20A, 20B may clip the package 100P.

The fixation member 20A is provided with a notch portion 201, and the fixation member 20B is provided with a notch portion 202.

The paired fixation members 20A, 20B position the semiconductor device 100 by their respective notch portions 201, 202.

For example, the paired fixation members 20A, 20B is provided movable in a direction in which a straight line joins the paired fixation members 20A, 20B. The distance between the paired fixation members 20A, 20B are adjusted by moving the paired fixation members 20A, 20B.

Before the semiconductor device 100 is placed on the support board 10, the distance between the paired fixation members 20A, 20B is enlarged. After the semiconductor device 100 is placed there, the distance between the paired fixation members 20A, 20B is reduced. The notch portions 201, 202 eventually come into contact with two diagonal corners of the package 100P, respectively. Thus, the semiconductor device 100 is held between and by the paired fixation members 20A, 20B. Thereby, the semiconductor device 100 is fixed with the position of the semiconductor device 100 determined in the two axial directions along the first surface 10a.

It should be noted that the fixation portions 20 are not limited to the paired fixation members 20A, 20B. To put it specifically, the fixation portions 20 may be in any shape as long as the fixation portions 20 fix the semiconductor device 100 in the predetermined position. For example, each fixation portion 20 may be a recessed portion provided to the first surface 10a of the support board 10. The position of the semiconductor device 100 may be fixed by: making the size of the recessed portions meet the external size of the package 100P; and fitting the package 100P into the recessed portions.

The probe portions 30 are provided movable in at least one axial direction with respect to the support board 10. The probe portions 30 are brought into contact with the conduction portions ML which are exposed to the outside through the lateral surfaces 100c of the package 100P of the semiconductor device 100. For example, the front end of each probe portion 30 is brought into contact with the end surface MLa of a corresponding one of the conduction portions ML.

The probe portions 30 are provided, for example, movable in a way that makes the probe portions 30 go closer to and away from the lateral surfaces 100c of the semiconductor device 100. This makes it possible to bring the front ends of the probe portions 30 in contact with the end surfaces MLa of the conduction portions ML by gradually bringing the probe portions 30 closer to the end surfaces MLa while the semiconductor device 100 is positioned to the support board 10.

A plurality of probe portions 30, for example, are provided to the support board 10. Let us assume that one of the probe portions 30 is a first probe portion 301 and the other of the probe portions 30 is a second probe portion 302.

The first probe portion 301 and the second probe portion 302 are provided opposed to each other in a way that the first probe portion 301 and the second probe portion 302 clip the semiconductor device 100 for example.

When placed opposed to each other in this manner, the first probe portion 301 and the second probe portion 302 come into contact with the respective end surfaces MLa in a way that holds the semiconductor device 100 between the first probe portion 301 and the second probe portion 302. Thereby, the contact between the semiconductor device 100 and the probe portions 30 are achieved with well-balanced force.

The probe portions 30 may be provided capable of being moved by driving portions 35 provided to the support board 10. Each driving portion 35 may include means for driving the corresponding one of the probe portions 30 by a transmission mechanism using gears, cams, links and the like, or means for driving the corresponding one of the probe portions 30 by a motor, a piezoelectric element, or the like.

In addition, each driving portion 35 may include means for making the corresponding one of the probe portions 30 movable along two or more axes. For example, each driving portion 35 may include means for making the corresponding one of the probe portions 30 movable along a total of three axes which are inclusive of: two axes orthogonal to each other along the first surface 10a; and one axis orthogonal to the first surface 10a. Furthermore, each driving portion 35 may include means for turning the corresponding one of the probe portions 30 along the first surface 10a, and changing the angle of the corresponding one of the probe portions 30 to the first surface 10a. Moreover, each driving portion 35 may include means for making the corresponding one of the probe portions 30 movable along a circular orbit.

The movement of the probe portions 30 may be achieved by operating the transmission mechanism manually.

The support board 10 may include a first wiring P1 and a second wiring P2.

The first wiring P1 electricity connects the first probe portion 301 or the second probe portion 302. A first potential V1 is given to the first wiring P1 via a first terminal T1. The first wiring P1 electricity connects a first terminal T1. The first potential V1 is given to the first wiring P1 from the outside via the first terminal T1.

The second wiring P2 electricity connects the second probe portion 302 or the first probe portion 301. A second potential V2, which is different from the first potential V1, is given to the second wiring P2 via a second terminal T2. The second wiring P2 electricity connects a second terminal T2. The second potential V2 is given to the second wiring P2 from the outside via the second terminal T2.

In the holder 110 for measurement of the embodiment, a switch portion 40 may be provided to the support board 10.

The switch portion 40 is configured to switch the connection between the first probe portion 301 and the first wiring P1 or the second wiring P2, as well as the connection between the second probe portion 302 and the second wiring P2 or the first wiring P1. In other words, the switch portion 40 is configured to switch whether the first wiring P1 electrically connects the first probe portion 301 or the second probe portion 302. In addition, the switch portion 40 is configured to switch whether the second wiring P2 electrically connects the second probe portion 302 or the first probe portion 301. The switching of the potential given to the first probe portion 301 (between the first potential V1 and the second potential V2) and the potential given to the second probe portion 302 (between the second potential V2 and the first potential V1) are achieved by the switching operation of the switch portion 40.

In this respect, the first potential V1 is a ground potential, for example. The second potential V2 is a working potential of the semiconductor device 100, for example.

The contact of the first probe portion 301 and the second probe portion 302 respectively to the end surfaces MLa of the conduction portions ML gives the first potential V1 or the second potential V2 to each wiring of the semiconductor chips CP in the package 100P.

It should be noted that in a case where the holder 110 for measurement includes three or more probe portions 300, each of the probe portions 30 may be configured to give the first potential V1 or the second potential V2, otherwise a potential different from the first potential V1 and the second potential V2. In addition, each of the probe portions 30 may be configured to receive a signal output from the semiconductor device 100, but not configured to give the potentials to the semiconductor device 100.

Next, descriptions will be provided for how the holder 110 for measurement of the embodiment holds the semiconductor device 100.

First of all, as shown in FIG. 4A, in a case where the first probe portion 301 and the second probe portion 302 are placed opposed to each other, the space between the first probe portion 301 and the second probe portion 302 is widened.

Subsequently, the semiconductor device 100 is placed in a manner that the semiconductor device covers the through-hole 15 of the support board 10. When the semiconductor device 100 is placed on the support board 10, the electrodes BP provided to the undersurface 100b of the package 100P are placed inside the through-hole 15, and the edge portions of the undersurface 100b of the package 100P are in contact with the first surface 10a of the support board 10.

While in this state, the semiconductor device 100 is fixed to the support board 10 by use of the fixation portions 20 (for example, the paired fixation members 20A, 20B). Thereby, the semiconductor device 100 is fixed to the predetermined position on the first surface 10a precisely.

Thereafter, as shown in FIG. 4B, the probe portions 30 are brought closer to the semiconductor device 100 by the driving portions 35. As the probe portions 30 are brought closer to the semiconductor device 100, the front ends of the probe portions 30 eventually come into contact with the end surfaces MLa of the conduction portions ML of the package 100P.

Each probe portion 30 may be configured in a way that makes its front end portion movable, and provides the movable front end portion to the probe portion 30 while the movable front end portion is biased by a spring. When each probe portion 30 come into contact with the corresponding end surface MLa, this configuration buffers the contact force given by the probe portion 30 to the end surface MLa, and thus offers a secure contact.

By this method, the semiconductor device 100 is fixed to the holder 110 for measurement, and electrical conduction is established between the probe portions 30 and the corresponding end surfaces MLa.

In the holder 110 for measurement of the embodiment, the top surface 100a and the undersurface 100b of the package 100P are opened because the probe portions 30 are brought into contact with the lateral surfaces 100c of the package 100P.

After the semiconductor device 100 is held by the holder 110 for measurement, the predetermined switching is carried out by the switch portion 40. Thus, the first potential V1 is given to the first terminal T1, and the second potential V2 is given to the second terminal T2. Thereby, the first potential V1 is given to the first probe portion 301 or the second probe portion 302 via the first wiring P1 and the switch portion 40, while the second potential V2 is given to the second probe portion 302 or the first probe portion 301 via the second wiring P2 and the switch portion 40. While in this state, the workings of the semiconductor device 100 are inspected.

The use of the holder 110 for measurement of the embodiment makes it possible to meet a more accurate inspection.

In general, when the workings of the semiconductor device 100 are inspected, a socket (a holder for measurement) is used which includes terminals to be brought into contact with the multiple electrodes BP provided to the undersurface 100b of the package 100P for the purpose of establishing electrical conduction between the electrodes BP and the terminals. For example, the socket is provided with multiple terminals, and the placement of the semiconductor device 100 on the socket brings the electrodes BP of the undersurface 100b of the package 100P into contact with the terminals of the socket. Subsequently, the workings of the semiconductor device 100 are inspected by applying a predetermined voltage to the semiconductor device 100 from the terminals of the socket via the electrodes BP of the semiconductor device 100.

In this case, the existence of the socket under the semiconductor device 100 hinders the picture of the undersurface 100b of the semiconductor device 100 from being captured.

The holder 110 for measurement of the embodiment is capable of securely capturing both the picture of the top surface 100a and the picture of the undersurface 100b of the held semiconductor device 100, because both the top surface 100a and the undersurface 100b are opened. This makes it possible for the holder 110 for measurement to meet the more accurate inspection.

### (Other Examples of Probe Portions)

Next, descriptions will be provided for other examples of the probe portions.

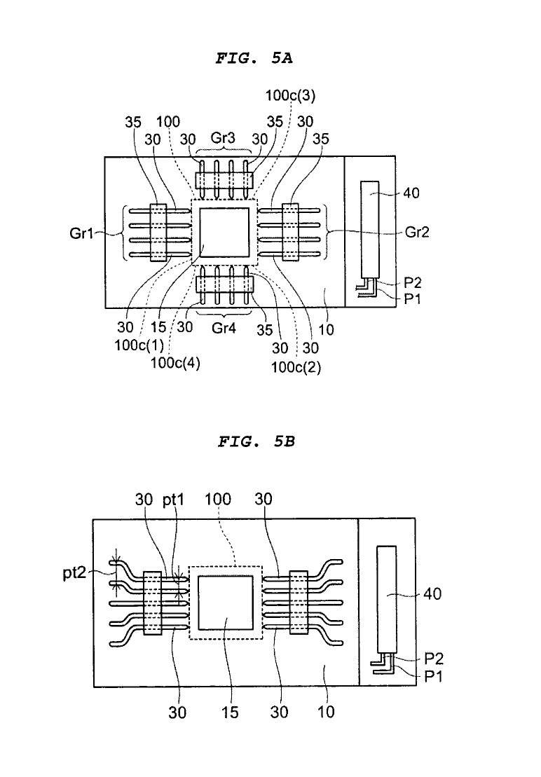

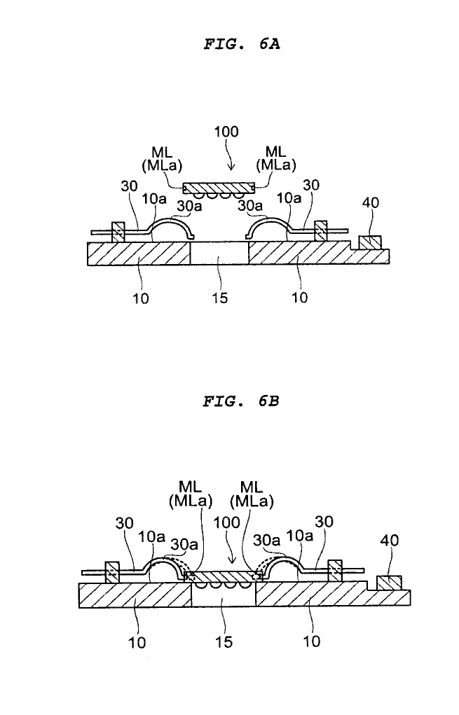

FIGS. 5A to 6B are schematic diagrams showing other examples of the probe portions.

FIG. 5A shows an example in which the probe portions 30 are provided directed to each of the four lateral surfaces 100c(1) to 100c(4) of the package 100P of the semiconductor device 100. The probe portions 30 are divided into four groups Gr1 to Gr4. The probe portions 30 of the group GR1 is placed corresponding to the lateral surface 100c(1). The probe portions 30 of the group GR2 is placed corresponding to the lateral surface 100c(2). The probe portions 30 of the group GR3 is placed corresponding to the lateral surface 100c(3). The probe portions 30 of the group GR4 is placed corresponding to the lateral surface 100c(4). The probe portions 30 of the group GR1 and the group GR2 are opposed to each other. The probe portions 30 of the group GR3 and the group GR4 are opposed to each other.

Each probe portion 30 is movably provided to the support board 10.

This makes it possible to bring the probe portions 30 into contact with the respective end surfaces MLa (see FIGS. 2A and 2B) which are exposed to the outside through the four lateral surfaces 100c(1) to 100c(4) of the package 100P.

FIG. 5B shows an example in which the pitch between the probe portions 30 is changed. For example, in a case where the probe portions 30 are provided opposed to one lateral surface 100c of the package 100P, the pitch pt1 between the probe portions 30 is narrower at a side closer to the semiconductor device 100 than a pitch pt2 at a side farther from the semiconductor device 100.

For example, the pitch pt1 between the probe portions 30 at the side closer to the semiconductor device 100 is equal to the pitch between the end surfaces MLa (see FIGS. 2A and 2B) which are exposed to the outside through the lateral surface 100c of the package 100P.

On the other hand, the pitch pt2 between the probe portions 30 at the side farther from the semiconductor device 100 is made wider than the pitch pt1. This makes it easy to pull the probe portions 30 out even in a case where the pitch between the multiple end surfaces MLa (see FIGS. 2A and 2B) is narrow.

FIGS. 6A and 6B show an example in which front end portions 30a of the respective probe portions 30 are curved. The probe portions 30 are placed opposed to each other in between the through-hole 15. As shown in FIG. 6A, the front end portions 30a of the respective probe portions 30 are in a curved shape. Because of this curved shape, the front end portions 30a thereof have a sprint property due to elastic deformation. As shown in FIG. 6B, when the front end portions 30a of the probe portions 30 are put into the corresponding lateral surfaces 100c while the semiconductor device 100 is positioned to the support board 10, the spring property of the front end portions 30a makes it possible to securely bring the probe portions 30 into contact with the end surfaces MLa (see FIGS. 2A and 2B) which are exposed to the outside through the lateral surfaces 100c while buffering the contact force between the probe portions 30 and the end surfaces MLa.

### Second Embodiment

Next, descriptions will be provided for a measurement apparatus of a second embodiment.

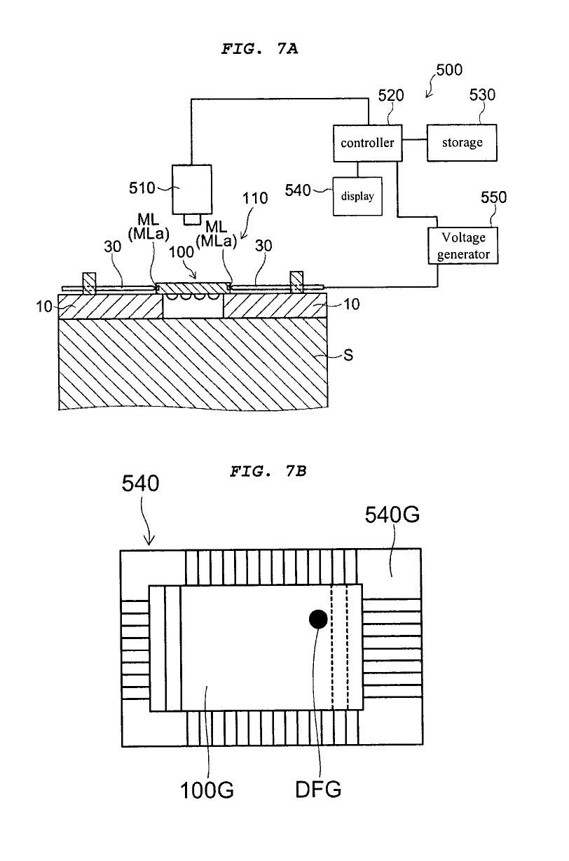

FIGS. 7A to 7B are schematic diagrams illustrating the measurement apparatus of the second embodiment.

FIG. 7A is a diagram showing the overall constitution of the measurement apparatus, and FIG. 7B is a diagram showing an example of what is displayed on a display.

As shown in FIG. 7A, a measurement apparatus 500 of the second embodiment is one configured to measure the electrical conduction characteristics of a semiconductor device 100 which is an example of an object of measurement (to detect where a short circuit takes place, for example).

The measurement apparatus 500 includes a holder 110 for measurement, a thermal detection camera (a thermal detection portion) 510, a controller 520 and a voltage generator 550. The measurement apparatus 500 further includes a storage 530 and a display 540.

As previously described, the holder 110 for measurement includes the support board 10, the fixation portions 20 (see FIGS. 1A and 1B), and the probe portions 30. The holder 110 for measurement is provided on a base S, for example. The holder 110 for measurement may be provided thereon in a way that is capable of adjusting an angle of turn of the holder 110 for measurement along the top surface of the base S and an angle of inclination of the holder 110 for measurement to the top surface thereof.

The voltage generator 550 is one configured to generate a voltage to be applied to the semiconductor device 100, from the probe portions 30 via the conduction portions ML (see FIGS. 2A and 2B). The voltage generator 550 generates a voltage which represents the first potential V1 to be given to the first probe portion 301 and the second potential V2 to be given to the second probe portion 302, for example.

The thermal detection camera 510 is a camera configured to capture a signal in accordance with heat produced from the semiconductor device 100 when the voltage is applied to the semiconductor device 100. The thermal detection camera 510 is an infrared camera, for example. The thermal detection camera 510 detects infrared light and the like, which are given off from the semiconductor device 100, while the semiconductor device 100 is in operation.

The controller 520 performs arithmetic on the location of the heat source of the semiconductor device 100 on the basis of the signal captured by the thermal detection camera 510. The result of the arithmetic is displayed on the display 540, for example.

FIG. 7B shows an example of what is displayed on the display 540. The display 540 displays a picture 540G which is captured by the thermal detection camera 510. An image 100G representing multiple stacked chips is displayed on the picture 540G. An image DFG indicating the location of the heat source on which the controller 520 performs the arithmetic is displayed on the image 100G while the image DFG overlaps the image 100G representing the semiconductor device 100.

The storage 530 is one in which to store the signal captured by the thermal detection camera 510, for example. The controller 520 obtains the location of the heat source of the semiconductor device 100 by: reading the signal which is stored in the storage 530; and applying a predetermined signal process to the signal thus read. Thereafter, the controller 520 causes the display 540 to display the location of the heat source of the semiconductor device 100.

In the measurement apparatus 500, the single controller 520 controls the thermal detection camera 510, the storage 530, the display 540 and the voltage generator 550. Instead, multiple controllers may control these portions. Otherwise, the controller 520 may be implemented by the processing of programs by a computer.

When the semiconductor device 100 is measured by use of the measurement apparatus 500, first of all, the semiconductor device 100 is fixed to the holder 110 for measurement. Subsequently, the probe portions 30 are brought into contact with the respective end surfaces MLa of the package 100P.

Thereafter, the voltage generated by the voltage generator 550 is given to the semiconductor device 100 via the probe portions 30.

After that, a picture (signal) representing the semiconductor device 100 is captured by the thermal detection camera 510. After captured for a certain length of time, the picture (signal) is stored in the storage 530, for example.

Subsequently, the controller 520 reads the signal, which is captured by the thermal detection camera 510, from the storage 530, for example, and performs the predetermined arithmetic. Thereafter, the controller 520 causes the result of the arithmetic to be displayed on the display 540. Thereby, the image DFG indicating the location of the heat source of the semiconductor device 100 is displayed on the display 540.

For example, in a case where a short circuit takes place in a semiconductor chip CP included in the semiconductor device 100, the amount of heat generation is greater in the location of the short circuit than in the rest of the semiconductor chip CP because the electrical resistivity in the location of the short circuit is greater than the electrical resistivity in the normal wiring pattern. By using this characteristic, the location of abnormal heat generation in the semiconductor device 100 is found from the signal captured by the thermal detection camera 510. The location of abnormal heat generation is a place in which a defect is most likely to have taken place.

In the measurement apparatus 500 of the embodiment, the top surface 100a of the semiconductor device 100 can be opened because the holder 110 for measurement brings the probe portions 30 into contact with the end surfaces MLa (see FIGS. 2A and 2B). This makes it possible for the picture of the top surface 100a of the semiconductor device 100 to be accurately captured by the thermal detection camera 510.

In addition, when the holder 110 for measurement, with the semiconductor device 100 fixed thereto, is placed on the base S upside down, the picture of the undersurface 100b of the semiconductor device 100 can be accurately captured through the through-hole 15 as well. Or when the semiconductor device 100 is placed upside down, the picture of the undersurface 100b of the semiconductor device 100 can be accurately captured.

In other words, the holder 110 for measurement enables the picture of the undersurface 100b of the semiconductor device 100 to be captured through the through-hole 15 without being blocked, because the holder 110 for the measurement brings the probe portions 30 into contact with the lateral surfaces 100c of the semiconductor device 100, and because the through-hole 15 is provided to the holder 110 for measurement on the side of the undersurface 100b of the semiconductor device 100.

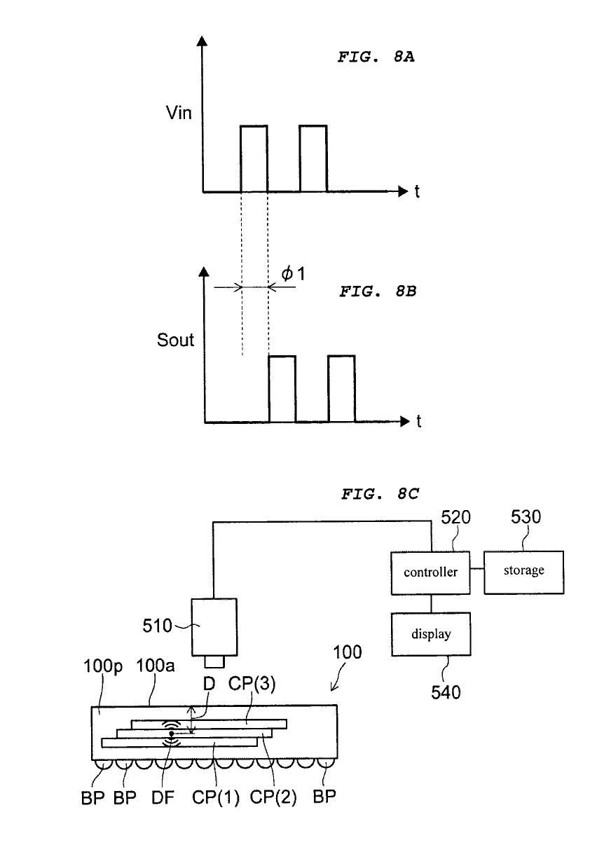

FIGS. 8A to 8C are diagrams showing an example of how the location of the heat source is detected.

FIG. 8A shows an example of how the voltage given to the semiconductor device 100 changes with time. In the graph shown in FIG. 8A, the horizontal axis represents time t, and the vertical axis represents an input voltage Vin. A pulse voltage with a predetermined frequency, for example, is given to the semiconductor device 100.

FIG. 8B shows an example of how the output of the signal captured by the thermal detection camera 510 changes with time. In the graph shown in FIG. 8B, the horizontal axis represents time t, and the vertical axis represents an output value Sout. The horizontal axis (time t) in FIG. 8B corresponds to the horizontal axis (time t) in FIG. 8A.

The pulse voltage, for example, is applied to the semiconductor device 100, and how heat is generated during the voltage application is captured by the thermal detection camera 510. The location of abnormal heat generation reacts to pulses of the pulse voltage, and the heat source is lit accordingly. Thereby, the location of the heat source is identified accurately.

In addition, as shown in FIGS. 8A and 8B, a phase difference φ1 occurs between a phase (first phase) of the voltage given to the semiconductor device 100 and a phase (second phase) of the signal captured by the thermal detection camera 510.

When the top surface 100a of the semiconductor device 100, for example, is chosen as a reference, this phase difference φ1 is related to the distance between the top surface 100a and the heat source (the depth from the top surface 100a).

Judging from the phase difference φ1 on the basis of this relationship, the controller 520 performs the arithmetic on the depth of the heat source from the top surface 100a.

FIG. 8C is a schematic diagram illustrating how the heat propagates from the heat source. If a defective point DF, which becomes the heat source, exists in the inside of the semiconductor device 100, the heat generated at the defective point DF spreads to its surrounding area. In this respect, let us assume a case where the heat occurs at a time when the voltage is applied to the semiconductor device 100. In this case, it takes certain time for the heat to propagate to the top surface 100a of the semiconductor device 100. The difference between the time when the voltage is applied to the semiconductor device 100 and the time when the signal in accordance with the heat of the heat source is detected by the thermal detection camera 510 appears as the phase difference φ1.

This phase difference φ1 is expressed, for example, with a model equation (Eq. 1) as follows:

φ1=(A*ta+B*tb)*N+C (Eq. 1)

where A denotes a thermal conduction coefficient of chips; B denotes a thermal conduction coefficient of die-attach films; N denotes the number of chips stacked one on another; to denotes a thickness of the chips; tb denotes a thickness of the die-attach films; and C denotes other factors. The die-attach films are those provided between the multiple stacked chips.

Judging from φ1 by use of the foregoing model equation (Eq. 1), the controller 520 performs the arithmetic on the depth D of the defective point DF from the top surface 100a, for example.

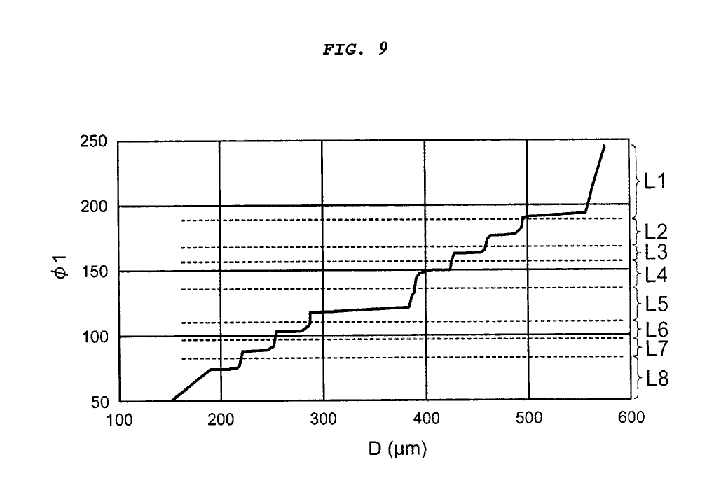

FIG. 9 is a diagram showing a relationship between the depth D and the phase difference φ1.

In the graph shown in FIG. 9, the horizontal axis represents the depth D, and the vertical axis represents the phase difference φ1. FIG. 9 shows the relationship between the depth D of the defective point from the top surface 100a and the phase difference yl in the semiconductor device 100 in which 8 chips are stacked one on another.

In this respect, reference signs L1 to L8 shown in FIG. 9 denotes the tiers in which the respective chips exist. To put it specifically, the tier of a chip whose value of the depth D is the largest (deepest) is shown as the first tier L1, and the tier of a chip whose value of the depth D is the smallest (shallowest) is shown as the 8th tier L8. The tiers L1 to L8 correspond respectively to the ranges into which the phase difference φ1 is divided. Which one of the tiers L1 to L8 the defective point is included in can be judged by which range the phase difference φ1 is included in.

Referring to a set of table data based on such a graph as shown in FIG. 9, for example, the controller 520 finds which one of the tiers L1 to L8 the defective point exists in from the phase difference φ1.

It should be noted that: the model equation (Eq. 1) is an example of its kind, and the equation is not limited to the one mentioned above; and the graph shown in FIG. 9 is an example of its kind, and the graph is not limited to the one shown in FIG. 9.

### Third Embodiment

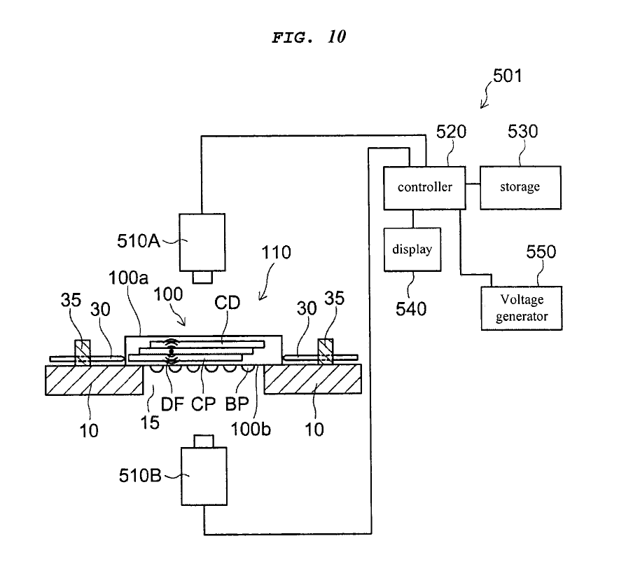

FIG. 10 is a schematic diagram illustrating a measurement apparatus of a third embodiment.

A measurement apparatus 501 shown in FIG. 10 is the same as the measurement apparatus 500 in that the measurement apparatus 501 includes the holder 110 for measurement, the controller 520, the storage 530, the display 540 and the voltage generator 550. However, the measurement apparatus 501 is different from the measurement apparatus 500 in that the measurement apparatus 501 includes two thermal detection cameras (a first thermal detection camera 510A and a second thermal detection camera 510B).

The first thermal detection camera 510A is placed on the side of the top surface 100a of the semiconductor device 100 fixed to the holder 110 for measurement. The second thermal detection camera 510B is placed on the side of the undersurface 100b of the semiconductor device 100 fixed to the holder 110 for measurement. The measurement apparatus 501 captures pictures from both the top surface 100a and the undersurface 100b of the semiconductor device 100 by use of the thermal detection cameras, respectively.

In the holder 110 for measurement, the through-hole 15 is provided to the support board 10. This enables the second thermal detection camera 510B to capture the picture (signal) representing the undersurface 100b of the semiconductor device 100 through the through-hole 15.

The signals captured by the first thermal detection camera 510A and the second thermal detection camera 510B are sent to the controller 520. On the basis of the signals sent from the first thermal detection camera 510A and the second thermal detection camera 510B, the controller 520 performs arithmetic on the location of a detective point DF, and the depth of the defective point DF from the top surface 100a, as well as causes the result of the arithmetic to be displayed on the display 540.

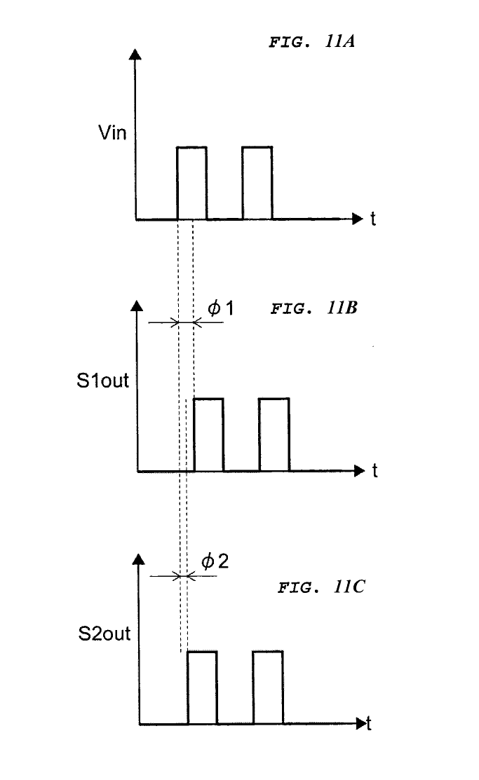

FIGS. 11A to 11C are diagrams showing an example of how the location of a head source is detected.

FIG. 11A shows an example of how a voltage given to the semiconductor device 100 changes with time. In the graph shown in FIG. 11A, the horizontal axis represents time t, and the vertical axis represents an input voltage Vin. A pulse voltage with a predetermined frequency, for example, is given to the semiconductor device 100.

FIG. 11B shows an example of how the output of a signal captured by the first thermal detection camera 510A changes with time. In the graph shown in FIG. 11B, the horizontal axis represents time t, and the vertical axis represents an output value S1out. The horizontal axis (time t) in FIG. 11B corresponds to the horizontal axis (time 1) in FIG. 11A.

FIG. 11C shows an example of how the output of a signal captured by the second thermal detection camera 510B changes with time. In the graph shown in FIG. 11C, the horizontal axis represents time t, and the vertical axis represents an output value S2out. The horizontal axis (time t) in FIG. 11C corresponds to the horizontal axes (time t) in FIGS. 11A and 11B.

As shown in FIGS. 11A and 11B, a phase difference φ1 takes place between a phase (first phase) of the voltage given to the semiconductor device 100 and a phase (second phase) of the signal captured by the first thermal detection camera 510A. This phase difference φ1 is related to the distance from the top surface 100a to the heat source (the defective point DF).

As shown in FIGS. 11A and 11C, a phase difference φ2 takes place between the phase (first phase) of the voltage given to the semiconductor device 100 and a phase (third phase) of a signal captured by the second thermal detection camera 510B. This phase difference φ2 is related to the distance from the undersurface 100b to the heat source (the defective point DF).

On the basis of these phase differences φ1, φ2, the controller 520 performs arithmetic on the distance from the top surface 100a to the defective point DF, and the distance from the undersurface 100b to the defective point DF. The controller 520 obtains the location of the defective point DF with high accuracy, for example, by using: the relationship between the distance from the top surface 100a to the defective point DF and the phase difference φ1 (referred to as a “first set of table data,” for example); and the relationship between the distance from the undersurface 100b to the defective point DF and the phase difference φ2 (referred to as a “second set of table data,” for example), as shown in FIG. 9.

With regard to the semiconductor device 100 in which, as shown in FIG. 9, 8 chips are stacked one on another, for example, let us assume a case where the controller 520 judges that a tier in which the defective point DF may exist is the fourth or 5th tier which is found from the first set of table data, and the third or fourth tier which is found from the second set of table data. In this case, the controller 520 finally judges that the fourth tier common in the preliminary judgment is the tier in which the defective point DF exists.

In the second embodiment, the tier in which a defective point DF exists is identified by use of the model equation (Eq. 1). The model equation (Eq. 1) includes the coefficient which has a range like the coefficient C, for example. For this reason, when the calculation is carried out using the model equation (Eq. 1), there is likelihood that many tiers including defective points DF exist.

In contrast, in the third embodiment, the measurement apparatus 501 is configured to measure a defective point DF from both the top surface 100a and the undersurface 100c of the package 100P by use of the thermal detection cameras 510A, 510B. This makes the measurement apparatus 501 capable of pinpointing the tier in which the defective point DF exists by using the two sets of table data even in a case where the tier in which the defective point DF exists could not be pinpointed if the measurement apparatus 501 would use one set of table data. Accordingly, the detection can be achieved with high accuracy.

### Fourth Embodiment

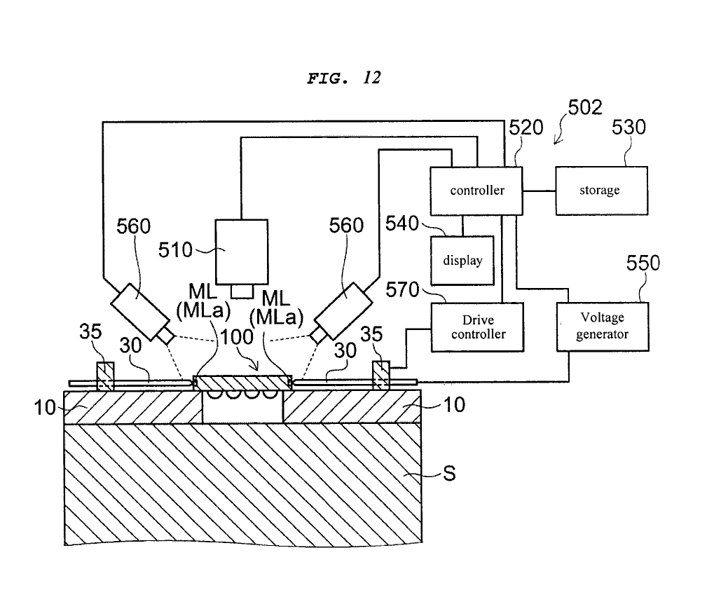

FIG. 12 is a schematic diagram illustrating a measurement apparatus of a fourth embodiment.

As shown in FIG. 12, a measurement apparatus 502 of the fourth embodiment is the same as the measurement apparatus 500 in that the measurement apparatus 502 includes the holder 110 for measurement, the thermal detection camera 510, the controller 520, the storage 530, the display 540 and the voltage generator 550. The measurement apparatus 502 is different from the measurement apparatus 500 in that the measurement apparatus 502 includes lateral-surface photographing cameras 560 and a drive controller 570.

The lateral-surface photographing cameras 560 capture pictures of the respective lateral surfaces 100c of the semiconductor device 100. The lateral-surface photographing cameras 560 are provided corresponding to the respective lateral surfaces 100c with which the probe portions 30 come into contact. In an example shown in FIG. 12, two lateral-surface photographing cameras 560 are provided corresponding to the respective two lateral surfaces 100c opposed to each other. Signals captured by the lateral-surface photographing cameras 560 are sent to the controller 520.

On the basis of the signals captured by the lateral-surface photographing cameras 560, the controller 520 performs arithmetic on the locations (three-dimensional locations, for example) of the end surfaces MLa of the conduction portions ML. The controller 520 sends information about the locations, which are obtained through the arithmetic, to the drive controller 570.

The drive controller 570 is the one configured to control the positions (positions of the front ends) of the probe portions 30 by giving a drive signal to the driving portions 35. The drive controller 570 gives the drive signal to the driving portions 35 on the basis of the information about the locations which is sent from the controller 520. The positions of the respective probe portions 30 are controlled by the drive controller 570. Incidentally, the drive controller 570 may be incorporated into the controller 520.

When the semiconductor device 100 is measured by use of the measurement apparatus 502 of the embodiment, first of all, the semiconductor device 100 is placed on the support board 10 with the probe portions 30 retracted, and the semiconductor device 100 is fixed to the support board 10 by the fixation portions 20 (see FIGS. 1A and 1B).

Subsequently, the pictures (signals) representing the lateral surfaces 100c of the semiconductor device 100 are captured, and are sent to the controllers 520, by use of the lateral-surface photographing cameras 560. On the basis of the signals captured by the lateral-surface photographing cameras 560, the controller 520 performs the arithmetic on the locations of the end surfaces MLa of the conduction portions ML. The controller 520 sends the information about the locations, which are obtained through the arithmetic, to the drive controller 570.

On the basis of the information about the locations which is sent from the controller 520, the drive controller 570 gives the drive signal to the driving portions 35. On the basis of this drive signal, the motors of the driving portions 35, for example, work by a predetermined amount. Thus, the probe portions 30 are brought into contact with the locations of the end surfaces MLa accurately.

Once the probe portions 30 are brought into contact with the end surfaces MLa, the voltage generated by the voltage generator 550 is given to the semiconductor device 100 from the probe portions 30. Subsequently, the picture (signal) representing the semiconductor device 100 is captured by the thermal detection camera 510. After captured for a certain length of time, the picture (signal) is stored in the storage 530, for example.

Thereafter, the controller 520 reads the signal, which is captured by the thermal detection camera 510, from the storage 530, for example, and performs predetermined arithmetic. Subsequently, the controller 520 causes the result of the arithmetic to be displayed on the display 540. Thereby, an image DFG (see FIG. 7B) indicating the location of the heat source of the semiconductor device 100 is displayed on the display 540.

The measurement apparatus 502 of the embodiment is capable of automatically bringing the probe portions 30 into contact with the end surfaces MLa of the lateral surfaces 100c, and of carrying out the measurement by bringing the probe portions 30 into contact with the end surfaces MLa quickly and accurately.

### Fifth Embodiment

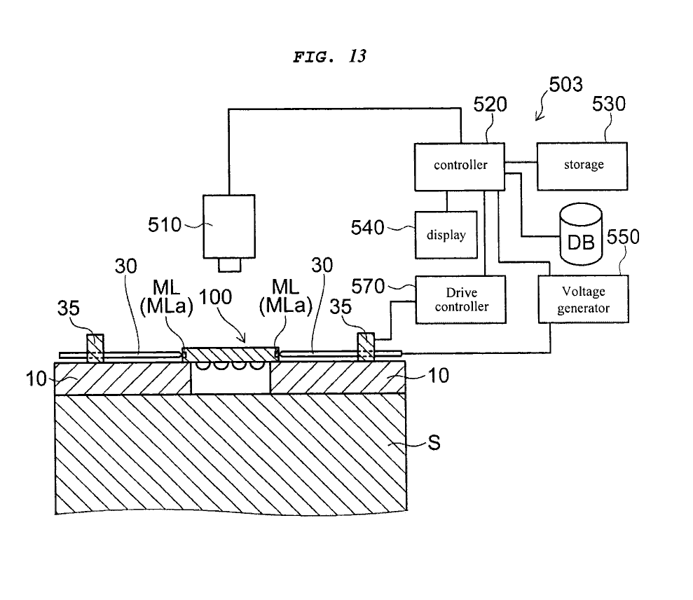

FIG. 13 is a schematic diagram illustrating a measurement apparatus of a fifth embodiment.

As shown in FIG. 13, a measurement apparatus 503 of the fifth embodiment is the same as the measurement apparatus 502 in that the measurement apparatus 503 includes the holder HO for measurement, the thermal detection camera 510, the controller 520, the storage 530, the display 540, the voltage generator 550 and the drive controller 570. However, the measurement apparatus 503 is different from the measurement apparatus 502 in that the measurement apparatus 503 is not provided with the lateral-surface photographing cameras 560.

In the measurement apparatus 503 of the embodiment, the controller 520 performs a process of acquiring design information about the semiconductor device 100 from a database DB in which the design information is stored. For example, in a case where location information about the end surfaces MLa is included in the design information, the controller 520 refers to the location information.

On the other hand, in a case where the location information about the end surfaces MLa is not included in the design information, the controller 520 calculates the location information about the end surfaces MLa with respect to the reference position of the semiconductor device 100 from the design information about the semiconductor device 100.

From the location information about the end surfaces MLa with respect to the reference position of the semiconductor device 100, the controller 520 calculates the locations of the end surfaces MLa with respect to the support board 10 while semiconductor device 100 is fixed to the holder 110 for measurement. The controller 520 sends information about the locations thus calculated to the drive controller 570.

On the basis of the information about the locations sent from the controller 520, the drive controller 570 gives a drive signal to the driving portions 35. The positions of the probe portions 30 are controlled by the drive controller 570. Incidentally, the drive controller 570 may be incorporated in the controller 520.

When the semiconductor device 100 is measured by use of the measurement apparatus 503 of the embodiment, first of all, the semiconductor device 100 is placed on the support board 10 with the probe portions 30 retracted, and the semiconductor device 100 is fixed to the support board 10 by the fixation portions 20 (see FIGS. 1A and 1B).

Subsequently, using the design information about the semiconductor device 100 read from the database DB, the controller 520 calculates the locations of the end surfaces MLa of the conduction portions ML, which are exposed to the outside through the lateral surfaces 100c, with respect to the support board 10. The controller 520 sends information about the locations thus calculated to the drive controller 570.

On the basis of the information about the locations which is sent from the controller 520, the drive controller 570 gives a drive signal to the driving portions 35. On the basis of this drive signal, the motors of the driving portions 35, for example, work by a predetermined amount. Thus, the probe portions 30 are brought into contact with the locations of the end surfaces MLa accurately.

Once the probe portions 30 are brought into contact with the end surfaces MLa, the voltage generated by the voltage generator 550 is given to the semiconductor device 100 from the probe portions 30. Subsequently, the picture (signal) representing the semiconductor device 100 is captured by the thermal detection camera 510. After captured for a certain length of time, the picture (signal) is stored in the storage 530, for example.

Thereafter, the controller 520 reads the signal, which is captured by the thermal detection camera 510, from the storage 530, for example, and performs predetermined arithmetic. Subsequently, the controller 520 causes the result of the arithmetic to be displayed on the display 540. Thereby, an image DFG (see FIG. 7B) indicating the location of the heat source of the semiconductor device 100 is displayed on the display 540.

On the basis of the design information about the semiconductor device 100, the measurement apparatus 503 of the embodiment is capable of automatically bringing the probe portions 30 into contact with the end surfaces MLa of the lateral surfaces 100c. Thereby, the measurement apparatus 503 is capable of carrying out the measurement by bringing the probe portions 30 into contact with the end surfaces MLa quickly and accurately without capturing the pictures of the lateral surfaces.

Next, descriptions will be provided for another application example.

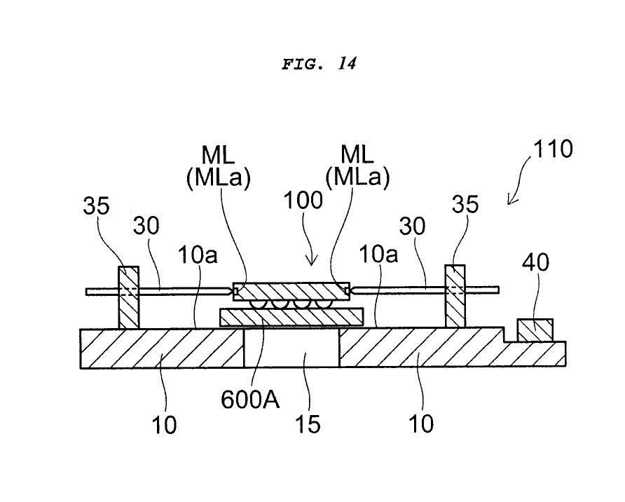

FIG. 14 is a schematic diagram showing another application example.

FIG. 14 shows how the semiconductor device 100, which is the object of measurement, is fixed to the holder 110 for measurement while mounted on a mounting board 600A.

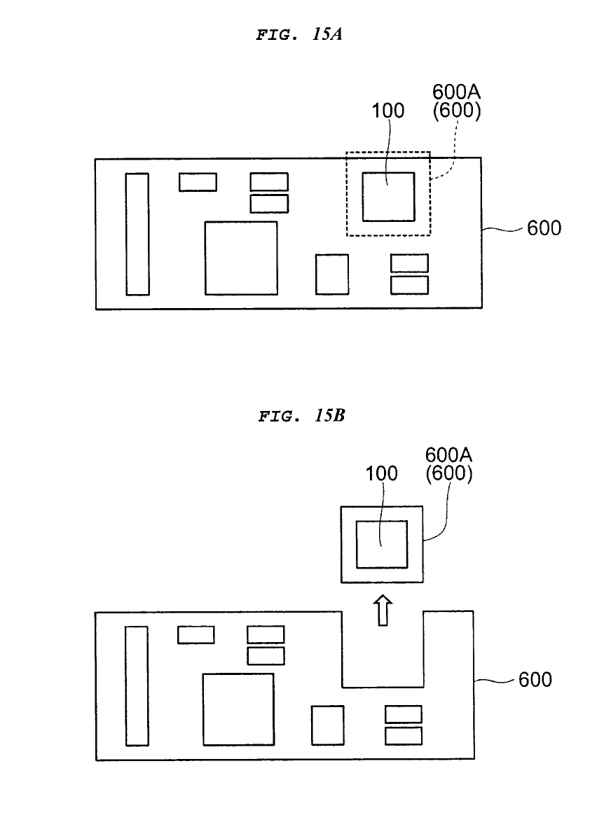

FIGS. 15A and 15B are schematic diagrams showing an example of the mounting board.

As shown in FIG. 15A, the semiconductor device 100 is mounted in a predetermined position on a mounting board 600, for example, by soldering. There is likelihood that in addition to the semiconductor device 100, other components are mounted on the mounting board 600.

FIG. 15B shows the mounting board 600 which is divided along a dashed line shown in FIG. 15A. The semiconductor device 100 is mounted on the mounting board 600A obtained by the division.

As shown in FIG. 14, the holder 110 for measurement of the embodiment is capable of fixing the semiconductor device 100 even while the semiconductor device 100 is in the state of being mounted on the mounting board 600A. In this case, the holder 110 for measurement fixes the semiconductor device 100 by holding the two diagonal corner portions of the package 100P of the semiconductor device 100, or the two diagonal corner portions of the divided mounting board 600A, between and by the paired fixation members 20A, 20B, for example, of the fixation portions 20 shown in FIGS. 1A and 1B.

Once the semiconductor device 100 is fixed there by the fixation portions 20, the probe portions 30 are brought into contact with the end portions MLa of the conduction portions ML which are exposed to the outside through the lateral surfaces 100c of the semiconductor device 100. This enables a predetermined voltage to be applied to the semiconductor device 100 from the probe portions 30.

The holder 110 for measurement of the embodiment is capable of fixing the semiconductor device 100 even while the semiconductor device 100 is in the state of being mounted on the mounting board 600A. For this reason, the holder 110 for measurement is capable of carrying out the measurement without detaching the semiconductor device 100 from the mounting board 600 (600A).

In general, after the semiconductor device 100 is mounted on the mounting board 600 as shown in FIG. 15A, the semiconductor device 100 is detached from the mounting board 600 when the semiconductor device 100 is intended to be inspected for a defective point. For example, the semiconductor device 100 is detached from the mounting board 600 by melting the solder by heating the semiconductor device 100. After the semiconductor device 100 is detached, the electrodes BP of the semiconductor device 100 are formed again, and the voltage is applied to the semiconductor device 100 via the re-formed electrodes BP.

However, when the semiconductor device 100 is heated in order to detach the semiconductor device 100 from the mounting board 600, the semiconductor device 100 is not a little affected by the heat. In a case where the semiconductor device 100 affected by the heat is inspected, it is difficult to identify the cause of the defect.

In a case where the holder 110 for measurement of the embodiment is used, the semiconductor device 100 is directly fixed to the holder 110 for measurement without: dividing the mounting board 600 around the semiconductor device 100 as shown in FIGS. 15A and 15B; or detaching the mounted semiconductor device 100 from the divided mounting board 600A.

Subsequently, the voltage can be applied to the semiconductor device 100 from the probe portions 30 via the end surfaces MLa of the conduction portions ML, which are exposed to the outside through the lateral surfaces 100c of the semiconductor device 100, by bringing the probe portions 30 into contact with the end surfaces MLa.

For this reason, the semiconductor device 100 can be accurately inspected for a defective point after the semiconductor device 100 is mounted without giving stress to the semiconductor device 100 due to the heat.

As described above, the holder for measurement and the measurement apparatuses make it possible to carry out the inspection with high accuracy.

It should be noted that although the foregoing descriptions have been provided for the embodiments and their modifications, the present invention is not limited to these examples.

For example, although in the embodiments, the relative positions of the thermal detection camera 510 and the object of measurement are fixed, the relative positions may be changed whenever deemed necessary. For example, the thermal detection camera 510 may be provided movable around the placement position of the object of measurement. Because the thermal detection camera 510 captures pictures of the object of measurement at various angles, the three-dimensional location of the defective point is detected.

In addition, the measurement apparatus of the third embodiment is capable of detecting the defective point with high accuracy by capturing pictures of the object of measurement at multiple angles. Specifically, the measurement apparatus of the third embodiment is capable of pinpointing the tier in which the defective point DF exists by using the multiple sets of table data even in a case where the tier in which the defective point DF exists could not be pinpointed if the measurement apparatus would use one set of table data. Accordingly, the detection can be achieved with high accuracy.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A holder for measurement configured to be capable of holding an object of measurement, the object of measurement included a package including a plurality of semiconductor chips and a conduction portion exposed to the outside through a lateral surface of the package,
comprising:
a support board including a through-hole;
a fixation portion configured to fix the object of measurement to the support board; and
a probe portion movable in at least one axial direction with respect to the support board, and configured to be capable of coming into contact with the conduction portion,
wherein the fixation portion includes paired fixation members provided to the support board.

2. A holder for measurement configured to be capable of holding an object of measurement, the object of measurement included a package including a plurality of semiconductor chips and a conduction portion exposed to the outside through a lateral surface of the package, comprising:
a support board including a through-hole;
a fixation portion configured to fix the object of measurement to the support board; and
a probe portion movable in at least one axial direction with respect to the support board, and configured to be capable of coming into contact with the conduction portion.

3. The holder for measurement of claim 2, wherein the wherein the fixation portion includes paired fixation members provided to the support board and configured to hold the package between the fixation members.

4. The holder for measurement of claim 2, wherein an end portion of the probe portion which is capable of coming into contact with the conduction portion has a spring property.

5. The holder for measurement of claim 3, wherein an end portion of the probe portion which is capable of coming into contact with the conduction portion has a spring property.

6. The holder for measurement of claim 2, comprising a plurality of the probe portions,
further comprising:
a first wiring configured to electrically communicate with one of a first probe portion and a second probe portion which are included in the plurality of probe portions, and given a first potential;
a second wiring configured to electrically communicate with the other one of the second probe portion and the first probe portion, and given a second potential different from the first potential; and
a switch portion configured to switch the connection of the first probe portion between the first wiring and the second wiring, as well as the connection of the second probe portion between the second wiring and the first wiring.

7. The holder for measurement of claim 3, comprising a plurality of the probe portions,
further comprising:
a first wiring configured to electrically communicate with one of a first probe portion and a second probe portion which are included in the plurality of probe portions, and given a first potential;
a second wiring configured to electrically communicate with the other one of the second probe portion and the first probe portion, and given a second potential different from the first potential; and
a switch portion configured to switch the connection of the first probe portion between the first wiring and the second wiring, as well as the connection of the second probe portion between the second wiring and the first wiring.

8. The holder for measurement of claim 5, comprising a plurality of the probe portions,
further comprising:
a first wiring configured to electrically communicate with one of a first probe portion and a second probe portion which are included in the plurality of probe portions, and given a first potential;
a second wiring configured to electrically communicate with the other one of the second probe portion and the first probe portion, given a second potential different from the first potential; and
a switch portion configured to switch the connection of the first probe portion between the first wiring and the second wiring, as well as the connection of the second probe portion between the second wiring and the first wiring.

9. A measurement apparatus configured to measure an electrical conduction characteristic of an object of measurement which includes: a package including a top surface, an undersurface and a lateral surface; an electrode provided to the undersurface; and a conduction portion exposed to the outside through the lateral surface, and configured to electrically communicate with the electrode, comprising:
a holder for measurement including a support board, a fixation portion and a probe portion, the support board including a through-hole in a position in which to place the object of measurement, the fixation portion configured to fix the object of measurement to the support board, and the probe portion provided movable in at least one axial direction with respect to the support board and configured to come into contact with the conduction portion;
a voltage generator configured to generate a voltage to be applied to the object of measurement from the probe portion via the conduction portion;
a thermal detection camera configured to capture a signal in accordance with heat produced from the object of measurement when the voltage is applied to the object of measurement; and
a controller configured to perform arithmetic on a location of a heat source of the object of measurement on the basis of the signal captured by the heat detection camera.

10. The measurement apparatus of claim 9, further comprising:
a lateral-surface photographing portion configured to capture an image of the lateral surface of the object of measurement fixed to the support board; and
a driving portion configured to drive the probe portion,
wherein the controller detects a location of the conduction portion from the image captured by the lateral-surface photographing portion, and instructs the driving portion to move the probe portion to the detected location.

11. The measurement apparatus of claim 10,
further comprising a driving portion configured to drive the probe portion,
wherein the controller instructs the driving portion to bring the probe portion into contact with the conduction portion in accordance with design information about the object of measurement.
